(19) United States
(12) Patent Application Publication
(10) Pub. No.: US 2025/0201662 A1
(43) Pub. Date: Jun. 19, 2025

(54) INTEGRATED CIRCUIT DEVICE INCLUDING THERMAL INTERPOSER LAYER

(71) Applicant: QUALCOMM Incorporated, San Diego, CA (US)

(72) Inventors: Je-Hsiung LAN, San Diego, CA (US); Jonghae KIM, San Diego, CA (US); Ranadeep DUTTA, Del Mar, CA (US)

(21) Appl. No.: 18/538,738

(22) Filed: Dec. 13, 2023

(51) Int. Cl. H01L 23/373; H01L 21/48; H01L 23/367; H01L 23/495; H01L 23/498; H01L 25/00; H01L 25/065

(52) U.S. Cl. CPC H01L 23/3738; H01L 21/4882; H01L 23/3677; H01L 23/49568; H01L 23/49816; H01L 23/49827; H01L 25/0655; H01L 25/50

(57) ABSTRACT

A device includes a die that includes a set of contacts coupled to a first side of the die. The die also includes active circuitry coupled to the set of contacts. The device also includes a thermal interposer layer (TIL) adjacent to the first side of the die. The TIL includes a thermally conductive material having one or more though hole vias (THVs) aligned with one or more first contacts of the set of contacts. The device further includes a set of conductive connectors that are coupled to the one or more first contacts and that extend through the THVs.

### FIELD

Various features relate to integrated circuit devices.

### BACKGROUND

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. Mobile package design has evolved to meet these divergent goals for enabling mobile applications that support multimedia enhancements. These mobile applications, however, are susceptible to overheating issues when one or more dies are arranged within the small form factor. In particular, system performance can be degraded making high-speed computing difficult due to limited heat dissipation.

### SUMMARY

Various features relate to integrated circuit devices.

One example provides a device that includes a die. The die includes a set of contacts coupled to a first side of the die. The die also includes active circuitry coupled to the set of contacts. The device also includes a thermal interposer layer (TIL) adjacent to the first side of the die. The TIL includes a thermally conductive material having one or more though hole vias (THVs) aligned with one or more first contacts of the set of contacts. The device further includes a set of conductive connectors that are coupled to the one or more first contacts and that extend through the THVs.

Another example provides a method of fabrication that includes forming a thermal interposer layer (TIL) including a thermally conductive material having one or more through hole vias (THVs). The method also includes forming a set of conductive connectors that are coupled to one or more first contacts of a die. The die includes a set of contacts coupled to a first side of the die. The die includes active circuitry coupled to the set of contacts. The set of contacts includes the one or more first contacts. The method further includes attaching the TIL to the die with the set of conductive connectors extending through the one or more THVs to couple to the one or more first contacts.

Another example provides a device that includes a first chiplet. The first chiplet includes a first set of contacts coupled to a first side of the first chiplet. The first chiplet also includes first active circuitry coupled to the first set of contacts. The device includes a first thermal interposer layer (TIL) adjacent to the first side of the first chiplet. The first TIL includes first thermally conductive material having one or more first though hole vias (THVs) aligned with one or more first contacts of the first set of contacts. The device further includes a first set of conductive connectors that are coupled to the one or more first contacts and that extend through the first THVs. The device also includes a package substrate including a set of substrate contacts. One or more first substrate contacts of the set of substrate contacts are coupled to the first set of conductive connectors.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1A illustrates a cross sectional profile view of an exemplary integrated circuit (IC) device including a thermal interposer layer (TIL).

FIG. 1B illustrates an example of the TIL and a cross sectional top view of the exemplary IC device of FIG. 1A.

FIG. 2A illustrates a cross sectional profile view of an exemplary IC device including a TIL.

FIG. 2B illustrates an example of the TIL and a cross sectional top view of the exemplary IC device of FIG. 2A.

FIG. 3A illustrates a cross sectional profile view of an exemplary IC device including a TIL.

FIG. 3B illustrates a top view of the exemplary IC device of FIG. 3A.

FIG. 4A illustrates a cross sectional profile view of an exemplary IC device that includes a TIL.

FIG. 4B illustrates an example of the TIL and a cross sectional top view of the exemplary IC device of FIG. 4A.

FIG. 5A illustrates a cross sectional profile view of an exemplary IC device that includes a TIL.

FIG. 5B illustrates examples of the TIL and a cross sectional top view of the exemplary IC device of FIG. 5A.

FIG. 6A illustrates a cross sectional profile view of an exemplary IC device that includes a TIL.

FIG. 6B illustrates an example of the TIL and a top view of a portion of the exemplary IC device of FIG. 6A.

FIG. 7 illustrates an example of a TIL and a cross sectional top view of a portion of an exemplary IC device that includes the TIL.

FIG. 8A illustrates Stages of an exemplary sequence for fabricating an exemplary IC device that includes a TIL.

FIG. 8B illustrates Stages of the exemplary sequence for fabricating the exemplary IC device that includes the TIL.

FIG. 8C illustrates Stages of the exemplary sequence for fabricating the exemplary IC device that includes the TIL.

FIG. 8D illustrates Stages of the exemplary sequence for fabricating the exemplary IC device that includes the TIL.

FIG. 8E illustrates Stages of the exemplary sequence for fabricating the exemplary IC device that includes the TIL.

FIG. 9 illustrates an exemplary flow diagram of a method for fabricating an exemplary IC device that includes a TIL.

FIG. 10 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For case of reference herein, such features are generally introduced as “one or more” features and are subsequently referred to in the singular or optional plural (as indicated by “(s)”) unless aspects related to multiple of the features are being described.

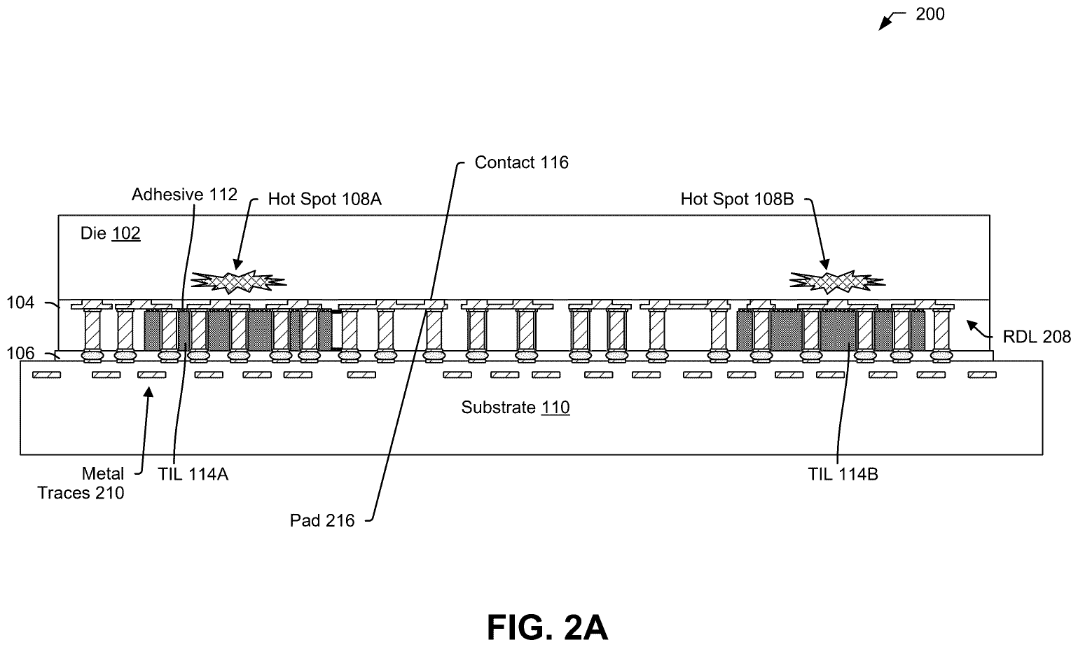

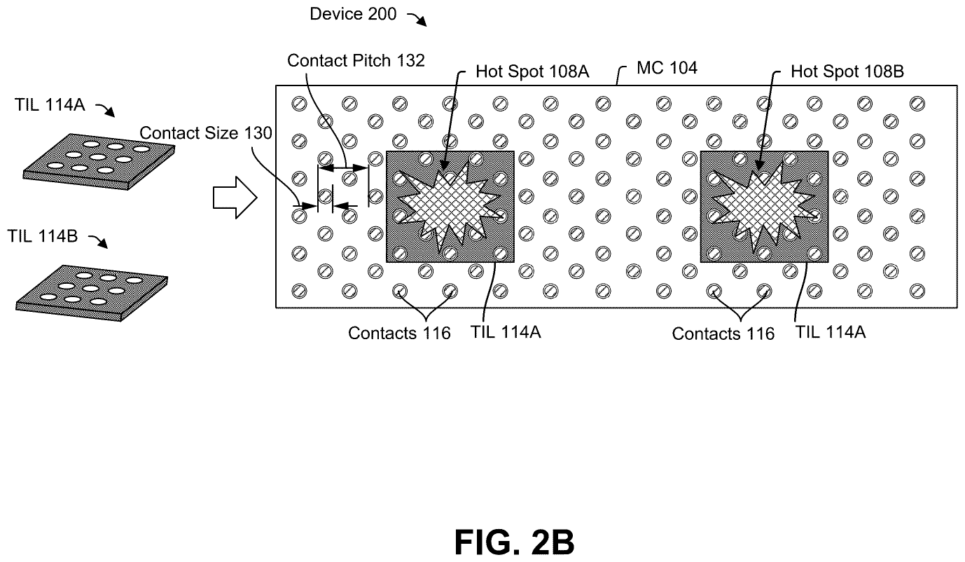

In some drawings, multiple instances of a particular type of feature are used. Although these features are physically and/or logically distinct, the same reference number is used for each, and the different instances are distinguished by addition of a letter to the reference number. When the features as a group or a type are referred to herein, e.g., when no particular one of the features is being referenced, the reference number is used without a distinguishing letter. However, when one particular feature of multiple features of the same type is referred to herein, the reference number is used with the distinguishing letter. For example, referring to FIG. 2A, multiple hot spots are illustrated and associated with reference numbers 108A and 108B. When referring to a particular one of these hot spots, such as a hot spot 108A, the distinguishing letter “A” is used. However, when referring to any arbitrary one of these hot spots or to these hot spots as a group, the reference number 108 is used without a distinguishing letter.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

State-of-the-art mobile application devices demand a small form factor, low cost, a tight power budget, and high electrical performance. Mobile package design has evolved to meet these divergent goals for enabling mobile applications that support multimedia enhancements. For example, fan-out (FO) wafer level packaging (WLP) or FO-WLP process technology is a development in packaging technology that is useful for mobile applications. This chip first FO-WLP process technology solution provides flexibility to fan-in and fan-out connections from a die to package balls. In addition, this solution also provides a height reduction of a first level interconnect between the die and the package balls of mobile application devices. These mobile applications, however, are susceptible to overheating issues when one or more dies are arranged within the small form factor.

Stacked die schemes and chiplet architectures are becoming more common as significant power performance area (PPA) yield enhancements are demonstrated for stacked die and chiplet architecture product lines. Various aspects of the present disclosure provide an IC device with a TIL to provide improved heat dissipation, resulting in improved computing performance.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

A 3D integrated circuit (3D IC) includes a set of stacked and interconnected dies. Generally, a 3D IC architecture can achieve higher performance, increased functionality, lower power consumption, and/or smaller footprint, as compared to providing the same circuitry in a monolithic die or in a two-dimensional (2D) IC structure.

Aspects of the present disclosure are directed to a IC device that uses a TIL to provide improved heat dissipation. In some aspects of the present disclosure, a TIL is disposed in a space adjacent to a hot spot of a die. Having the TIL can improve performance and increase a lifetime of components of an IC device.

### Exemplary IC Devices Including Thermal Interposer Layer

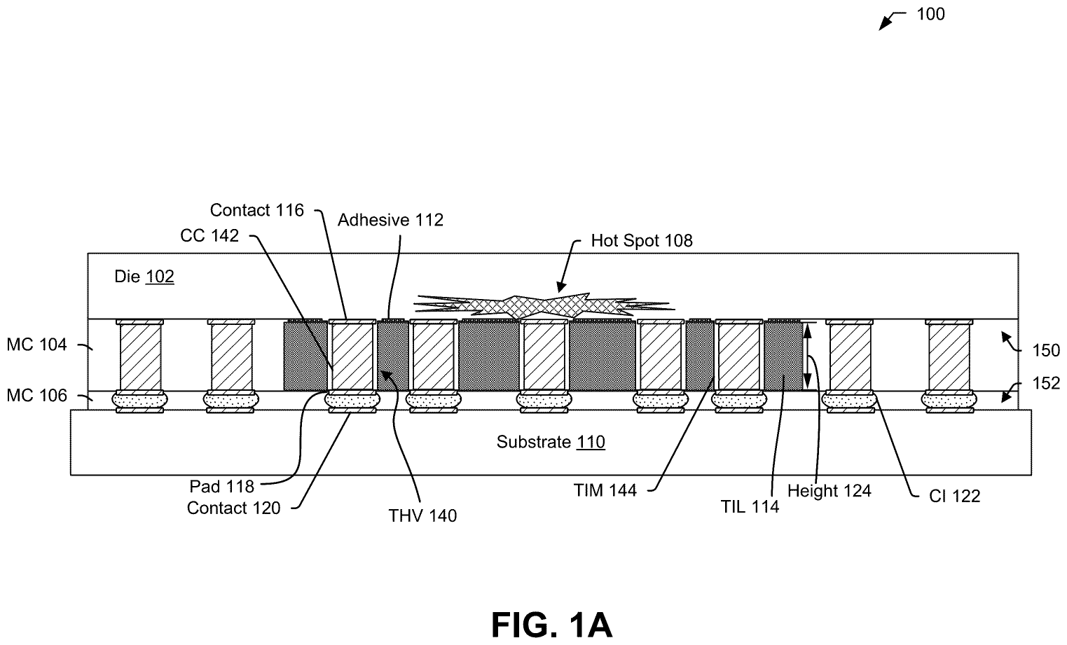

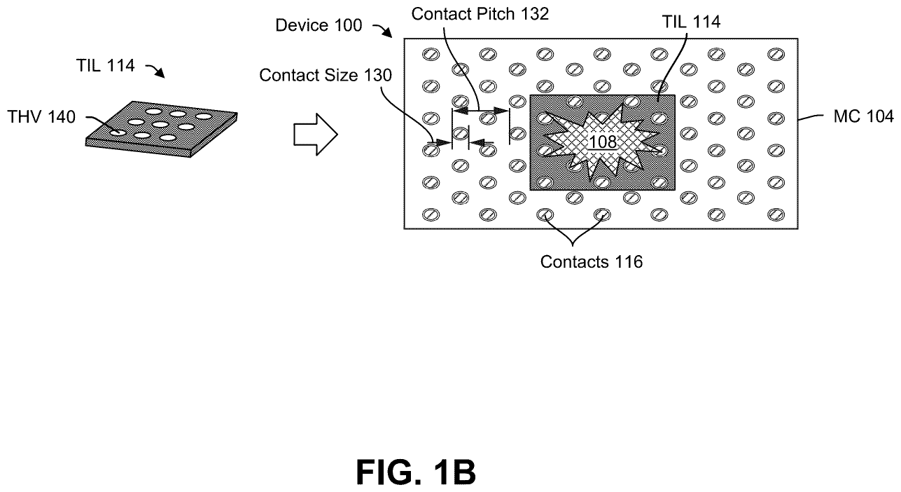

FIG. 1A illustrates a cross sectional profile view of a device 100 (e.g., an exemplary IC device) that includes a thermal interposer layer (TIL) 114. FIG. 1B illustrates an example of the TIL 114 and a cross sectional top view of the device 100.

The device 100 includes a die 102. The die 102 can include integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In a particular aspect, the die 102 can include a complementary metal oxide semiconductor (CMOS) chip, a power amplifier, a low-noise amplifier (LNA), a switch, a filter, or a combination thereof. In some implementations, a front end of line (FEOL) process may be used to fabricate the integrated circuitry in and/or over the semiconductor substrate.

The die 102 includes a set of contacts 116 coupled to a side 150 of the die 102. In a particular embodiment, the die 102 includes active circuitry coupled to the contacts 116. The active circuitry includes, for example, processing logic blocks (e.g., transistor blocks), memory blocks, etc. The device 100 includes a TIL 114 adjacent to the side 150 of the die 102. In a particular embodiment, the TIL 114 is positioned adjacent to a hot spot 108 of the die 102 and dissipates heat from the die 102. The TIL 114 includes a thermally conductive material having one or more though hole vias (THVs) 140. In a particular embodiment, the thermally conductive material includes alumina ceramic, aluminum nitride, silicon carbide (SiC), or a combination thereof. The THVs 140 are aligned with one or more of the contacts 116. The device 100 includes a set of conductive connectors (CCs) 142 that are coupled to at least some of the contacts 116. For example, one or more CCs 142 are coupled to respective contacts 116 and extend through the THVs 140. The CCs 142 can be electrically conductive, thermally conductive, or both.

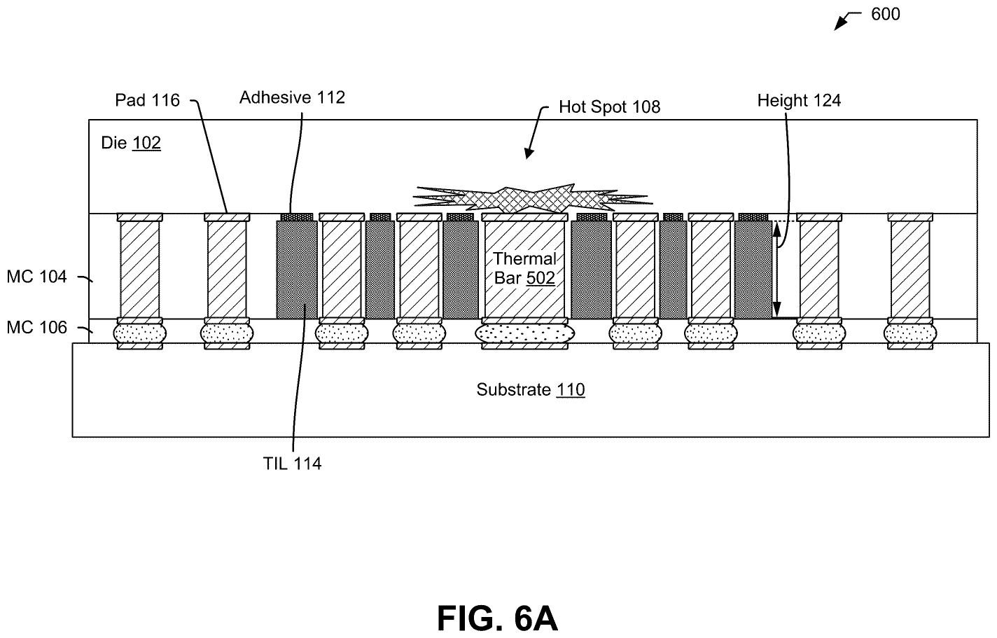

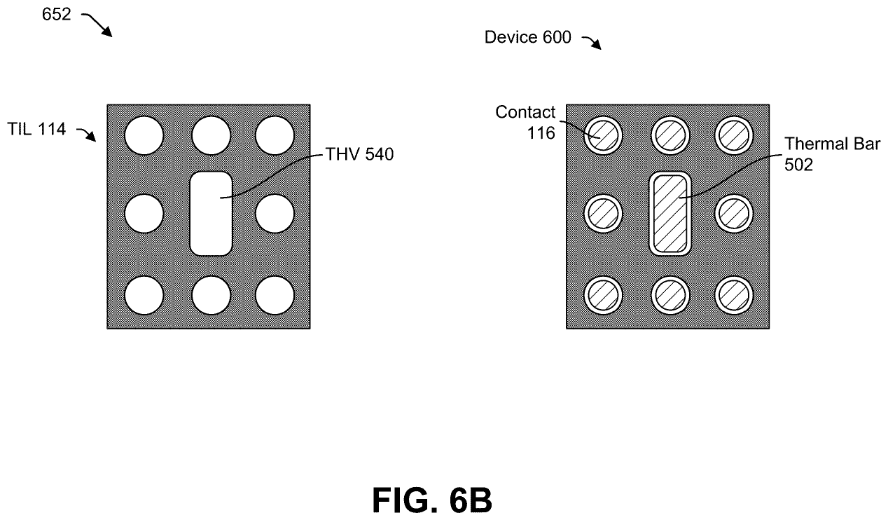

In FIG. 1B, each of the THVs 140 is illustrated as having a substantially circular cross-section as an example. In other examples, a THV 140 can have a differently-shaped cross-section. To illustrate, at least one of the THVs 140 can have a substantially circular cross-section, a substantially oblong cross-section, a substantially square cross-section, or a combination thereof, as further described with reference to FIG. 6B.

The device 100 also includes a substrate 110 (e.g., a package substrate) including a set of contacts 120 coupled to a side 152 of the substrate 110. One or more contacts 120 are coupled to respective conductive connectors 142. For example, each contact 120 is coupled via a conductive interconnect (CI) 122 and a pad 118 to a corresponding CC 142. The circuitry of the die 102 is thus electrically connected, via a conductive path including the contact 116, the CC 142, the pad 118, the CI 122, and the contact 120, to the substrate 110. In a particular embodiment, the die 102 corresponds to a chiplet that is separated from the substrate 110 by the TIL 114.

In some implementations, the die 102 includes input/output (I/O) circuitry, and one or more of the CCs 142 are connected to the I/O circuitry to provide a data path between the die 102 and a second device that is coupled to the substrate 110. As one illustrative example, the second device can include a Dynamic Random-Access Memory (DRAM) chip (or chiplet). In this illustrative example, the I/O circuitry of the die 102 can include or correspond to interface circuitry (e.g., serializer/deserializer (SerDes) circuitry, a double data rate (DDR)-type DRAM bus interface circuit), memory buffers, and/or other circuitry that facilitates interaction between the active circuitry of the die 102 and the DRAM. In some implementations, the I/O circuitry can be connected to other devices in addition to or instead of the second device. For example, the I/O circuitry can interact with one or more other devices on a printed circuit board via one or more CCs 142.

In a particular embodiment, one or more of the contact 116, the CC 142, the pad 118, the CI 122, or the contact 120 include an electrically conductive material, such as copper, tin, aluminum, silver, gold, lead, bismuth, or a combination thereof. In a particular embodiment, one or more of the contact 116, the CC 142, the pad 118, the CI 122, or the contact 120 can include an electrically conductive material that is not included in another of the contact 116, the CC 142, the pad 118, the CI 122, or the contact 120. In a particular embodiment, one or more of the contact 116, the CC 142, the pad 118, the CI 122, or the contact 120 include material that is thermally conductive. For example, one or more of the contact 116, the CC 142, the pad 118, the CI 122, or the contact 120 are used for electrical signal propagation, thermal propagation, or both.

In a particular embodiment, the CCs 142 correspond to copper pillars, the CIs 122 correspond to solder bumps, and the contacts 116, the contacts 120, and the pad 118 correspond to metal pads. Pillars, bumps, and pads are used as illustrative examples of shapes of components (e.g., the CC 142, the CI 122, the contact 116, the contact 120, and the pad 118) of the device 100. In other examples, one or more components (e.g., the CC 142, the CI 122, the contact 116, the contact 120, or the pad 118) of the device 100 can have a different shape, such as a pillar, a pad, a bump, a ball, a trace, etc.

In FIG. 1A, the TIL 114 has a height 124 (e.g., 40-80 micrometers) between the die 102 and the substrate 110. In FIG. 1B, a distance between a first contact 116 and a next contact 116 corresponds to a contact pitch 132. A distance between a first edge of a contact 116 and an opposite edge of the contact 116 corresponds to a contact size 130.

In some implementations, the device 100 includes thermal interface material (TIM) 144 between the CC 142 and the TIL 114. For example, the TIM 144 corresponds to a thermally conductive gap filler that can be referred to as a thermal gap filler (TFG). In a particular embodiment, the TIM 144 can include silver-tin (AgSn) solder paste, silicone, polyurethane, or both. In a particular aspect, the TIM 144 is used to fill gaps between the TIL 114 and the CCs 142 (that extend through the TIL 114) to provide efficient thermal conduction from the TIL 114 to the CIs 122, which can enable further heat dissipation via the CCs 142.

In some implementations, the device 100 includes adhesive 112 between the TIL 114 and the die 102. In a particular aspect, the adhesive 112 corresponds to photo-definable adhesive or dry-film adhesive. In some implementations, the device 100 includes mold compound (MC) 104 at least partially encapsulating the die 102, the contacts 116, the adhesive 112, the CCs 142, the TIL 114, the TIM 144, or a combination thereof. In some implementations, the device 100 includes MC 106 at least partially encapsulating the pads 118, the CIs 122, the contacts 120, the substrate 110, or a combination thereof. In an example, the MC 104, the MC 106, or both, include epoxy, silicone, polyimide, alumina, or a combination thereof.

In a particular aspect, one or more of the CCs 142 (e.g., a thermal bar) provide a primary path for thermal dissipation which is improved by the TIL 114. The TIL 114 improves overall thermal conductivity to dissipate heat from the die 102 as compared to using only mold compound (e.g., the MC 104, the MC 106, or both) for heat dissipation. In a particular aspect, having the TIL 114 reduces a temperature rise (e.g., by 16 degrees Celsius) of the device 100 as compared to using only mold compound for heat dissipation. In a particular embodiment, the thermally conductive material of the TIL 114 has a first thermal conductivity (e.g., 36 Watts per meter Kelvin (W/mK)) that is greater than a second thermal conductivity (e.g., 1.3 W/mK) of the MC 104, a third thermal conductivity of the MC 106, or both. The TIL 114 thus improves heat dissipation and enables higher computing performance within a small form factor of the device 100.

FIG. 2A illustrates a cross sectional profile view of a device 200 (e.g., an exemplary IC device) including a TIL 114A and a TIL 114B, and FIG. 2B illustrates an example of the TIL 114A and the TIL 114B and a cross sectional top view of the device 200 of FIG. 2A.

The device 200 of FIG. 2A includes many of the same components and features as are described above with reference to FIGS. 1A and 1B. Such components and features are physically and operationally the same as described above with reference to FIGS. 1A and 1B and are labeled in FIGS. 2A and 2B using the same reference numbers. In some implementations, the device 200 includes all of the same features and components as the device 100 of FIGS. 1A and 1B; however, some components and features illustrated in FIGS. 1A and B have been omitted from (or are not labeled with reference numbers in) FIGS. 2A and 2B for simplicity of illustration and to highlight differences between the device 100 and the device 200. Omission of such features and reference numbers should not be understood as limiting the features and components of FIGS. 2A and 2B to only those specifically called out below. For example, while FIG. 2A does not show active circuitry of the die 102, the die 102 can include active circuitry, as described with reference to FIGS. 1A and 1B.

In the example illustrated in FIGS. 1A and 1B, the device 100 includes a die 102 with a single TIL 114 adjacent to a single portion (e.g., corresponding to the hot spot 108) of the die 102. In the example illustrated in FIGS. 2A and 2B, the device 200 includes a die 102 with a TIL 114A adjacent to a first portion (e.g., corresponding to a hot spot 108A) of the die 102 and a TIL 114B adjacent to a second portion (e.g., corresponding to a hot spot 108B) of the die 102. Note that the device 200 including two TILs 114 adjacent to two portions of the die 102 illustrated in FIGS. 2A and 2B is merely one example. In other examples, the device 200 can include more than two TILs 114 adjacent to respective portions of the die 102 without departing from the scope of the disclosure.

In FIG. 2A, the device 200 includes a redistribution layer (RDL) 208 on the side 150 of the die 102. The RDL 208 electrically connects the contacts 116 of the dic 102 to pads 216 on the CCs 142. For example, a contact 116 is connected via the RDL 208 to one or more pads 216. A pad 216 is connected via a CC 142, a pad 118, and a CI 122 to a contact 120 on the side 152 of the substrate 110. In a particular embodiment, the substrate 110 includes metal traces 210 to electrically connect various contacts 120 to each other, to one or more other dies of the device 200, to one or more other devices, or a combination thereof. In a particular aspect, the device 200 includes adhesive 112 between portions of the RDL 208 and portions of the TILs 114A and 114B.

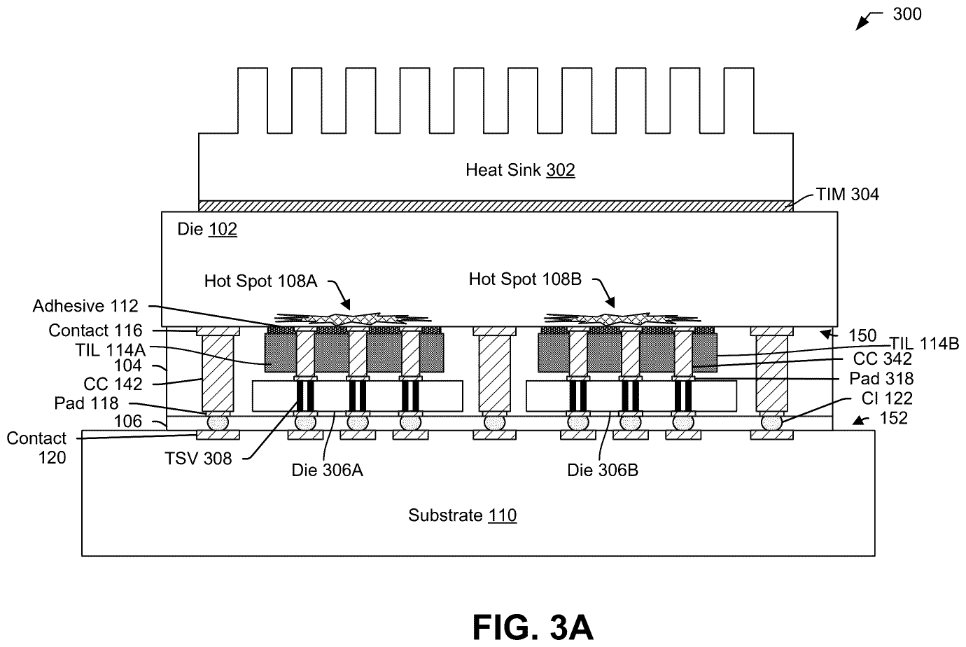

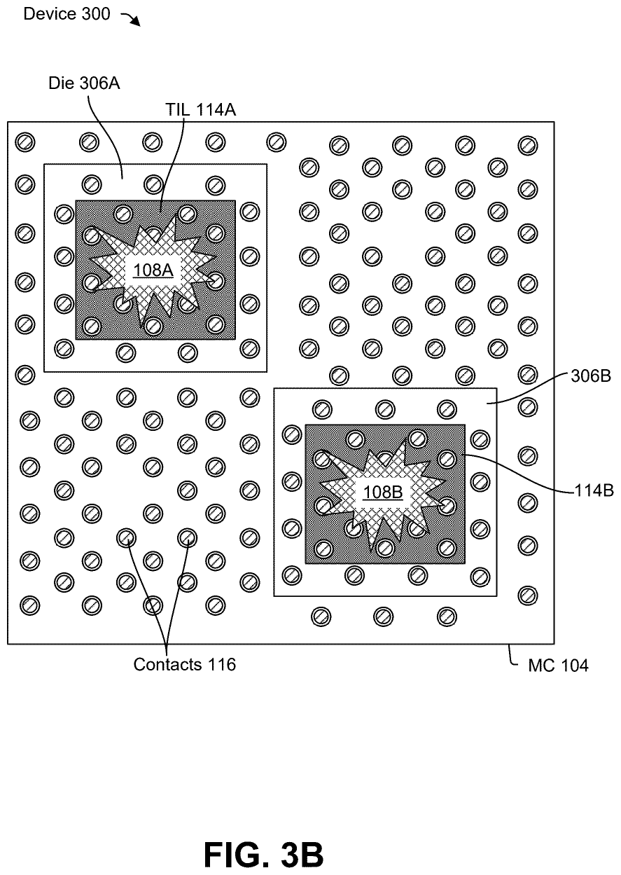

FIG. 3A illustrates a cross sectional profile view of a device 300 (e.g., an exemplary stacked IC device) that includes a TIL 114A and a TIL 114B, and FIG. 3B illustrates a top view of the device 300 of FIG. 3A. The device 300 includes many of the same components and features as are described above with reference to FIGS. 1A to 2B. Such components and features are physically and operationally the same as described above and are labeled using the same reference numbers. In some implementations, the device 300 includes all of the same features and components as the device 100 of FIGS. 1A and 1B and/or the device 200 of FIGS. 2A and 2B; however, some such components and features have been omitted from (or are not labeled with reference numbers in) FIGS. 3A and 3B for simplicity of illustration and to highlight differences between the devices 100, 200, and 300. Omission of such features and reference numbers should not be understood as limiting the features and components of FIGS. 3A and 3B to only those specifically called out below.

In the examples illustrated in FIGS. 1A and 2A, one or more TILs 114 are between a die 102 and a substrate 110. In the example illustrated in FIGS. 3A and 3B, one or more additional dies 306 are between one or more TILs 114 and the substrate 110. For example, a die 306A is between the TIL 114A and the substrate 110 and a die 306B is between the TIL 114B and the substrate 110. In a particular embodiment, one or more CCs 342 extend through the TILs 114 and one or more through-silicon vias (TSVs) 308 extend through the dies 306. In a particular embodiment, the TIL 114A is adjacent to a first portion of the die 102 that corresponds to a hot spot 108A and the TIL 114B is adjacent to a second portion of the die 102 that corresponds to a hot spot 108B. The CCs 342, the TSVs 308, one or more pads 318, or a combination thereof, include various electrically conductive materials, such as copper, tin, aluminum, silver, gold, or a combination thereof. In a particular embodiment, at least one of a CC 342, a TSV 308, or a pad 318 includes a first electrically conductive material that is not included in another one of a CC 342, a TSV 308, or a pad 318. In a particular embodiment, one or more of the CC 342, the TSV 308, or the pad 318 include material that is thermally conductive. For example, one or more of the CC 342, the TSV 308, or the pad 318 are used for electrical signal propagation, thermal propagation, or both.

The substrate 110 includes contacts 120 on the side 152 of the substrate 110. The contacts 120 are electrically connected via the CIs 122 to the pads 118, as described with reference to FIG. 1A. A first subset of the pads 118 is electrically connected via the CCs 142 to a first subset of the contacts 116. A second subset of the pads 118 is electrically connected via the TSVs 308 to pads 318, and the pads 318 are electrically connected via the CCs 342 to a second subset of the contacts 116. For example, a pad 118 is electrically connected, via a CC 142 that extends through the MC 104, to a contact 116. As another example, a pad 118 is electrically connected, via a TSV 308 that extends through the die 306A, to a pad 318. The pad 318 is electrically connected, via a CC 342 that extends through the TIL 114A, to a contact 116. As yet another example, a pad 118 is electrically connected, via a TSV 308 that extends through the die 306B, to a pad 318. The pad 318 is electrically connected, via a CC 342 that extends through the TIL 114B, to a contact 116.

In FIG. 3B, the contacts 116 are illustrated as having the same contact size. In FIG. 3A, the first subset of the contacts 116 that are on the CCs 142 have a first contact size that is different from (e.g., is greater than) a second contact size of the second subset of contacts 116 that are on the CCs 342. In a particular embodiment, the device 300 includes a TIM 304 between a heat sink 302 and the die 102. The TIM 304 is adjacent to a side of the die 102 that is opposite the side 150. The heat sink 302 is configured to provide additional heat dissipation for the die 102 of the device 300.

In a particular embodiment, the die 306A corresponds to a first high-bandwidth memory (HBM) module and the die 306B corresponds to a second HBM module. The first HBM module (e.g., the die 306A) includes a first set of conductive connectors (e.g., including first TSVs 308) that extend through the first HBM module and that are aligned with a first set of CCs 342 that extend through the TIL 114A to a first set of contacts 116. The second HBM module (e.g., the die 306B) includes a second set of conductive connectors (e.g., including second TSVs 308) that extend through the second HBM module and that are aligned with a second set of CCs 342 that extend through the TIL 114B to a second set of contacts 116.

In some implementations, the die 102 is a first chiplet, the die 306A is a second chiplet, and the die 306B is a third chiplet, and the first chiplet, the second chiplet, and the third chiplet are designed to operate in conjunction with each other. To illustrate, in some implementations, the active circuitry of the first chiplet/die 102 includes one or more first functional circuit blocks, the circuitry of the second chiplet/die 306A includes one or more second functional circuit blocks, and the circuitry of the third chiplet/die 306B includes one or more third functional circuit blocks, where the one or more first functional circuit blocks, the one or more second functional circuit blocks, the one or more third functional circuit blocks, or a combination thereof, are operationally dependent upon one another.

Forming the device 300 using chiplets arranged and interconnected as a 3D stacked IC can provide various benefits as compared to providing the same functional circuitry in one monolithic chip. For example, each chiplet is smaller than a monolithic die including all of the same functional circuit blocks would be. Since yield loss in IC manufacturing tends to increase as the die size increases, using smaller dies can reduce yield loss (i.e., increase yield) of the IC manufacturing process. Another benefit is that the chiplets can be fabricated in different locations and/or by different manufacturers, and in some cases, using different fabrication technologies (e.g., different fabrication technology nodes). As an example, one die of a chiplet-based integrated device (e.g., the die 102 of the device 300) can include components (e.g., interconnects, transistors, etc.) that have a first minimum size, and another die of the chiplet-based integrated device (e.g., the die 306A of the device 300) can include components (e.g., interconnects, transistors, etc.) that have a second minimum size, where the second minimum size is greater than the first minimum size. In contrast, all of the circuitry of a monolithic die is fabricated using the same fabrication technologies and equipment. As a result, when manufacturing a monolithic die, the entire die may be subject to the tightest manufacturing constraint of the most complex component of the monolithic die. In contrast, when using chiplets, different chiplets can be manufactured using different fabrication technologies (e.g., different fabrication technology nodes), and only the chiplet or chiplets that include the most complex components are subjected to the tightest manufacturing constraints. In this arrangement, chiplets fabricated using less expensive and/or higher yield fabrication technologies can be integrated with chiplets fabricated using more expensive and/or lower yield fabrication technologies to form an IC (e.g., the device 300), resulting in overall savings. Still further, in some cases, as technology improves, the design of a chiplet can be changed. Chiplet stacking allows such new chiplet designs to be integrated with older chiplet designs to form stacked IC devices, which improves manufacturing flexibility and reduces design costs.

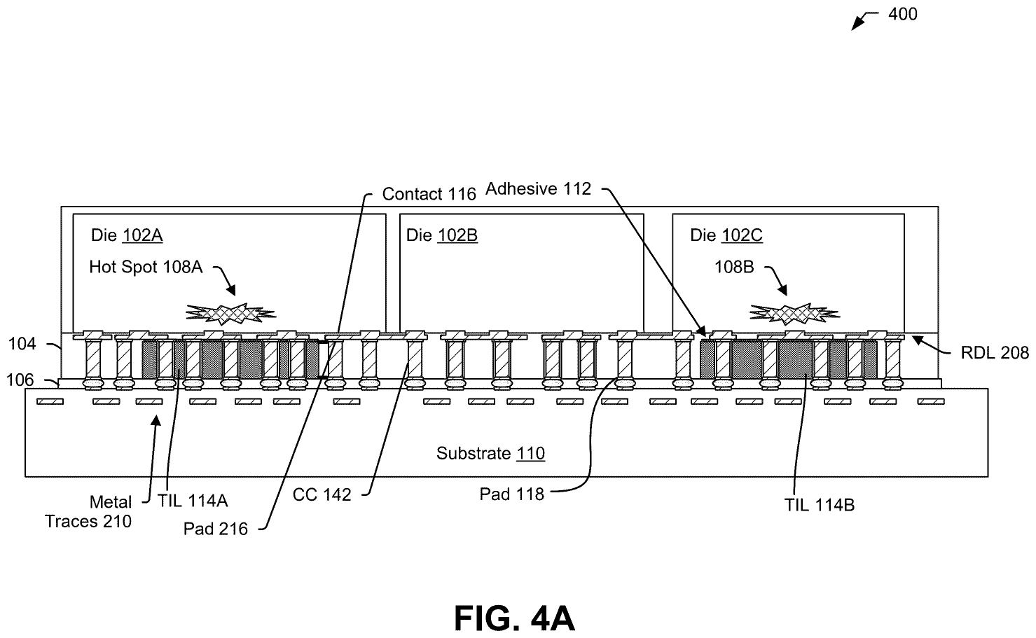

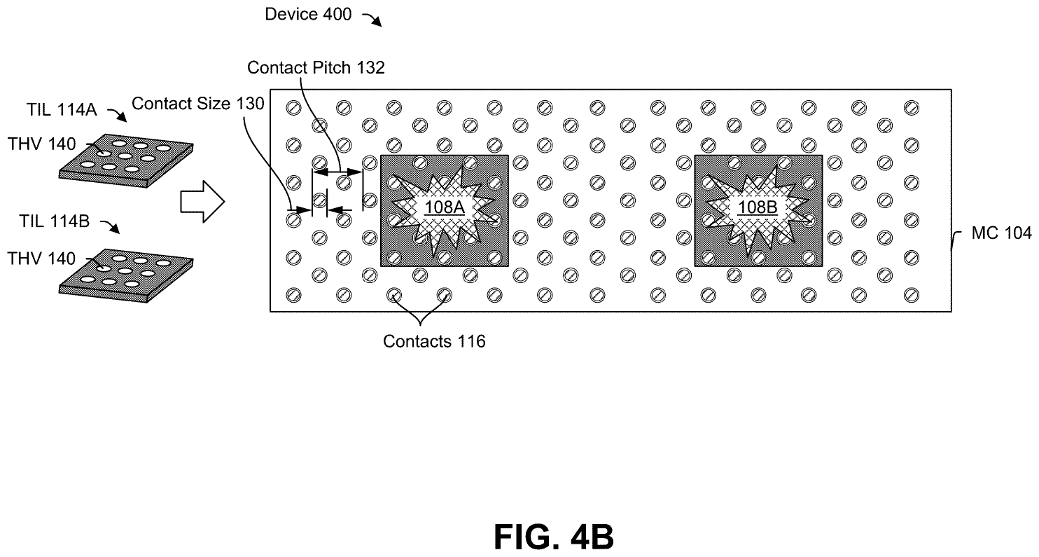

FIG. 4A illustrates a cross sectional profile view of a device 400 (e.g., an exemplary IC device) including a TIL 114A and a TIL 114B, and FIG. 4B illustrates an example of the TIL 114A and the TIL 114B and a cross sectional top view of the device 400 of FIG. 4A.

The device 400 includes many of the same components and features as are described above with reference to FIGS. 1A to 3B. Such components and features are physically and operationally the same as described above and are labeled using the same reference numbers. In some implementations, the device 400 includes all of the same features and components as the device 100 of FIGS. 1A and 1B, the device 200 of FIGS. 2A and 2B, and/or the device 300 of FIGS. 3A and 3B; however, some such components and features have been omitted from (or are not labeled with reference numbers in) FIGS. 4A and 4B for simplicity of illustration and to highlight differences between the devices 100, 200, 300, and 400. Omission of such features and reference numbers should not be understood as limiting the features and components of FIGS. 4A and 4B to only those specifically called out below.

In the example illustrated in FIGS. 4A and 4B, the device 400 includes multiple dies 102 and TILs 114 that are adjacent to one or more of the dies 102. For example, the device 400 includes a die 102A, a die 102B, and a die 102C. The device 400 also includes a TIL 114A adjacent to a side of the die 102A and a TIL 114B adjacent to a side of the die 102C. It should be understood that the device 400 including three dies is provided as an illustrative example, in other examples the device 400 can include fewer than three or more than three dies 102.

In a particular embodiment, the device 400 includes a RDL 208 between the dies 102 and the TILS 114 and/or the MC 104. The RDL 208 electrically connects contacts 116 of the dies 102 to pads 216 of CCs 142. In an example, a first set of CCs 142 extend from a first set of pads 216 to a first set of pads 118. The first set of pads 216 are electrically connected via a first portion of the RDL 208 to a first set of contacts 116 coupled to a first side of the die 102A. The first set of contacts 116 are electrically connected to first active circuitry of the die 102A. The device 400 includes a TIL 114A adjacent to the first side of the die 102A. The TIL 114A includes one or more first THVs 140 that extend through the TIL 114A and that are aligned with the first set of contacts 116. A subset of the first set of CCs 142 extend through one or more first THVs 140 of the TIL 114A.

In another example, a second set of CCs 142 extend from a second set of pads 216 to a second set of pads 118. The second set of pads 216 are electrically connected via a second portion of the RDL 208 to a second set of contacts 116 coupled to a first side of the die 102B. The second set of contacts 116 are electrically connected to second active circuitry of the die 102B. The second set of CCs 142 extends through the MC 104 and do not extend through any TILs.

In yet another example, a third set of CCs 142 extend from a third set of pads 216 to a third set of pads 118. The third set of pads 216 are electrically connected via a third portion of the RDL 208 to a third set of contacts 116 coupled to a first side of the die 102C. The third set of contacts 116 are electrically connected to third active circuitry of the die 102C. The TIL 114B includes one or more second THVs 140 that extend through the TIL 114B and that are aligned with the third set of contacts 116. A subset of the third set of CCs 142 extend through one or more second THVs 140 of the TIL 114B.

The pads 118 are electrically connected via the CIs 122 and the contacts 120 to the metal traces 210 of the substrate 110, as described with reference to FIG. 2A. In an example, a first set of contacts 120 are electrically connected to the first set of CCs 142, a second set of contacts 120 are electrically connected to the second set of CCs 142, and a third set of contacts 120 are electrically connected to the third set of CCs 142.

In some implementations, the die 102A is a first chiplet, the die 102B is a second chiplet, and the die 102C is a third chiplet, and the first chiplet, the second chiplet, and the third chiplet are designed to operate in conjunction with each other. To illustrate, in some implementations, the active circuitry of the first chiplet/die 102A includes one or more first functional circuit blocks, the circuitry of the second chiplet/die 102B includes one or more second functional circuit blocks, and the circuitry of the third chiplet/die 102C includes one or more third functional circuit blocks, where the one or more first functional circuit blocks, the one or more second functional circuit blocks, the one or more third functional circuit blocks, or a combination thereof, are operationally dependent upon one another.

The die 102A (e.g., the first chiplet) is separated from the substrate 110 by the TIL 114A, and the die 102C (e.g., the third chiplet) is separated from the substrate 110 by the TIL 114B. In a particular embodiment, the die 102A includes a system-on-chip (SOC) device, the die 102B includes a LNA, a switch, or both, and the die 102C includes a radio frequency power amplifier (RF-PA). In a particular aspect, overheating can reduce performance of the die 102A (e.g., the SOC device) and the die 102C (e.g., the RF-PA). The improved thermal dissipation provided by the TIL 114A and the TIL 114B can increase performance of the die 102A and the die 102C. In a particular aspect, a TIL 114 increases a lifetime of one or more components of the device 400. For example, the TIL 114B increases a high-temperature operating life (HTOL) of the RF-PA (e.g., a gallium arsenide (GaAs) power amplifier). In an illustrative example, having the TIL 114B can double the HTOL of the RF-PA.

In FIG. 4B, the TIL 114A and the TIL 114B are illustrated as having THVs 140 having the same size that corresponds to (e.g., is greater than or equal to) the contact size 130 and having a distance that correspond to (e.g., is less than or equal to) the contact pitch 132. In other examples, the TIL 114B has second THVs 140 having a different size, a different shape, a different pitch, or a combination thereof, as first THVs 140 of the TIL 114A to accommodate a second contact size 130, a second contact pitch 132, and a second contact shape of the third set of contacts 116 of the die 102C that are different from a first contact size 130, a first contact pitch 132, and/or a first contact shape of the first set of contacts 116 of the die 102A.

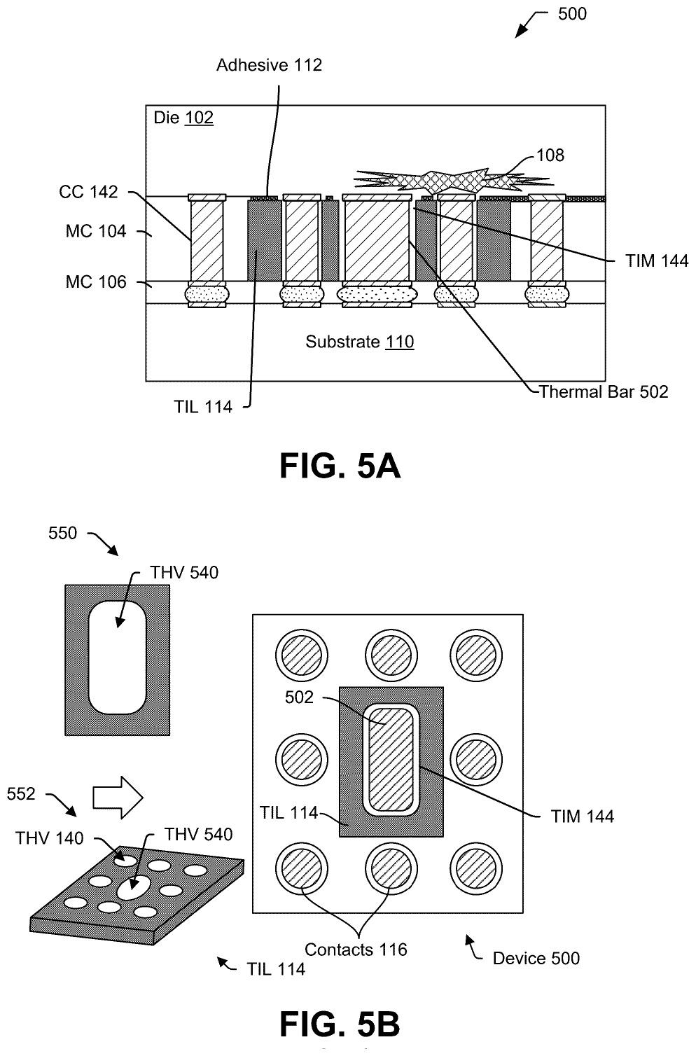

FIG. 5A illustrates a cross sectional profile view of a device 500 (e.g., an exemplary IC device) that includes a TIL 114, and FIG. 5B illustrates examples of the TIL 114 and a cross sectional top view of the device 500 of FIG. 5A.

The device 500 includes many of the same components and features as are described above with reference to FIGS. 1A to 4B. Such components and features are physically and operationally the same as described above and are labeled using the same reference numbers. In some implementations, the device 500 includes all of the same features and components as the device 100 of FIGS. 1A and 1B, the device 200 of FIGS. 2A and 2B, the device 300 of FIGS. 3A and 3B, and/or the device 400 of FIGS. 4A and 4B; however, some such components and features have been omitted from (or are not labeled with reference numbers in) FIGS. 5A and 5B for simplicity of illustration and to highlight differences between the devices 100, 200, 300, 400, and 500. Omission of such features and reference numbers should not be understood as limiting the features and components of FIGS. 5A and 5B to only those specifically called out below.

In the example illustrated in FIGS. 5A and 5B, the device 500 includes a thermal bar 502 that extends through a THV 540 of a TIL 114. For example, one or more of the CCs 142 correspond to thermal bars 502 that extend through THVs 540 of the TIL 114. The thermal bar 502 is configured to dissipate additional heat of the device 500. In a particular aspect, one or more of the CCs 142 that extend through the THVs 140 of the TIL 114 are connected to the I/O circuitry of the die 102 to provide a data path between the die 102 and a second device that is coupled to the substrate 110.

In a particular embodiment, the device 500 includes TIM 144 between the thermal bar 502 and the TIL 114. In a particular aspect, the device 500 includes TIM 144 between the TIL 114 and a subset of the CCs 142 that extend through the TIL 114.

In FIG. 5B, an example 550 of the TIL 114 includes a THV 540 having a shape that corresponds to (e.g., matches) a shape of the thermal bar 502 and having a size that corresponds to (e.g., is greater than or equal to) a size of the thermal bar 502. An example 552 of the TIL 114 includes the THV 540 and also includes one or more THVs 140 that have a shape that corresponds to (e.g., matches) a shape of contacts 116 and have a size that corresponds to (e.g., is greater than or equal) to a size of the contacts 116. In a particular embodiment, the thermal bar 502 has a non-circular cross-section and the THV 540 has a non-circular cross-section that can accommodate the cross-section of the thermal bar 502. For example, the thermal bar 502 has a first oblong cross-section and the THV 540 has a second oblong cross-section that is large enough to accommodate (e.g., fit) the first oblong cross-section and the TIM 144. The cross-sectional top view of the device 500 includes the example 550 of the TIL 114. In another embodiment, the device 500 can include the example 552 of the TIL 114.

FIG. 6A illustrates a cross sectional profile view of a device 600 (e.g., an exemplary IC device) that includes a TIL 114, and FIG. 6B illustrates an example of the TIL 114 and a top view of a portion of the device 600 of FIG. 6A.

The device 600 includes many of the same components and features as are described above with reference to FIGS. 1A to 5B. Such components and features are physically and operationally the same as described above and are labeled using the same reference numbers. In some implementations, the device 600 includes all of the same features and components as the device 100 of FIGS. 1A and 1B, the device 200 of FIGS. 2A and 2B, the device 300 of FIGS. 3A and 3B, the device 400 of FIGS. 4A and 4B, and/or the device 500 of FIGS. 5A and 5B; however, some such components and features have been omitted from (or are not labeled with reference numbers in) FIGS. 6A and 6B for simplicity of illustration and to highlight differences between the devices 100, 200, 300, 400, 500, and 600. Omission of such features and reference numbers should not be understood as limiting the features and components of FIGS. 6A and 6B to only those specifically called out below.

In the example illustrated in FIGS. 5A and 5B, the device 500 includes a thermal bar 502 that is offset from the hot spot 108 of the die 102. For example, the hot spot 108 corresponds to a portion of the die 102 that is adjacent to a CC 142 that is not a thermal bar 502. In the example illustrated in FIGS. 6A and 6B, an end of the thermal bar 502 is adjacent to a portion of the die 102 that corresponds to the hot spot 108. In FIG. 6B, an example 652 of the TIL 114 includes the THV 540 and one or more THVs 140 that have a shape that corresponds to (e.g., matches) a shape of the contacts 116 and have a size that corresponds to (e.g., is greater than or equal to) a size of the contacts 116. The cross-sectional top view of the device 600 includes the example 652 of the TIL 114.

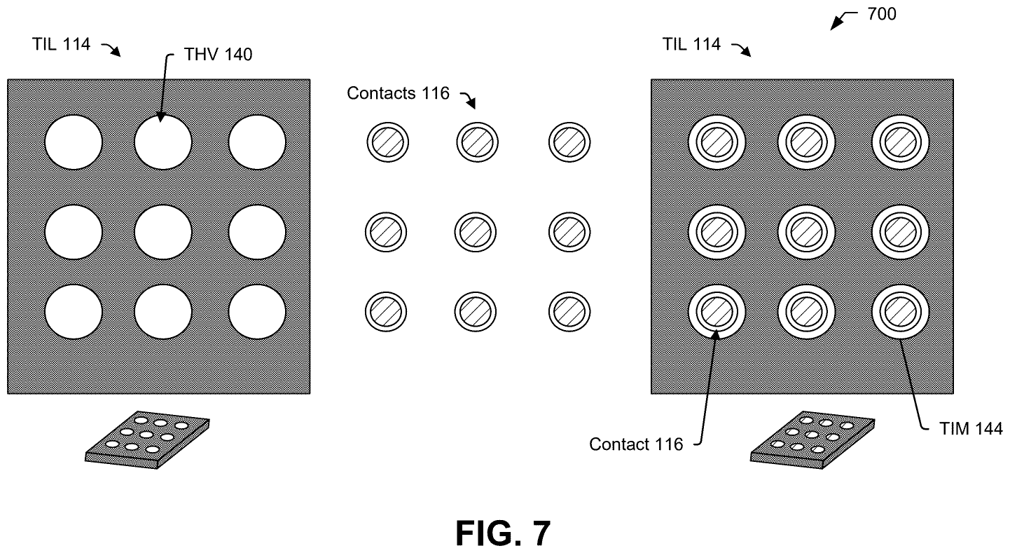

FIG. 7 illustrates an example of a TIL 114 and a cross sectional top view of a portion of a device 700 (e.g., an exemplary IC device) that includes the TIL 114. The TIL 114 includes THVs 140 having a shape that corresponds to (e.g., matches) a shape of the contacts 116 and having a size that corresponds to (e.g., is greater than or equal to) a size of the contacts 116. The cross-sectional top view of a portion of the device 700 includes the TIM 144 between the contacts 116 and the TIL 114.

While each of FIGS. 1A-7 illustrate examples of IC devices that include one or more dies and one or more TILs 114, the IC devices disclosed herein can be integrated with or included within a wide variety of other devices. For example, a device disclosed herein that includes one or more dies and one or more TILs 114 can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SIC) based integrated device, a memory, power management processor, and/or combinations thereof. In such devices, a die or chiplet can operate as any of these components (or a combination of these components) that includes active circuitry.

### Exemplary Sequence for Fabricating an Integrated Circuit Device Including a Thermal Interposer Layer

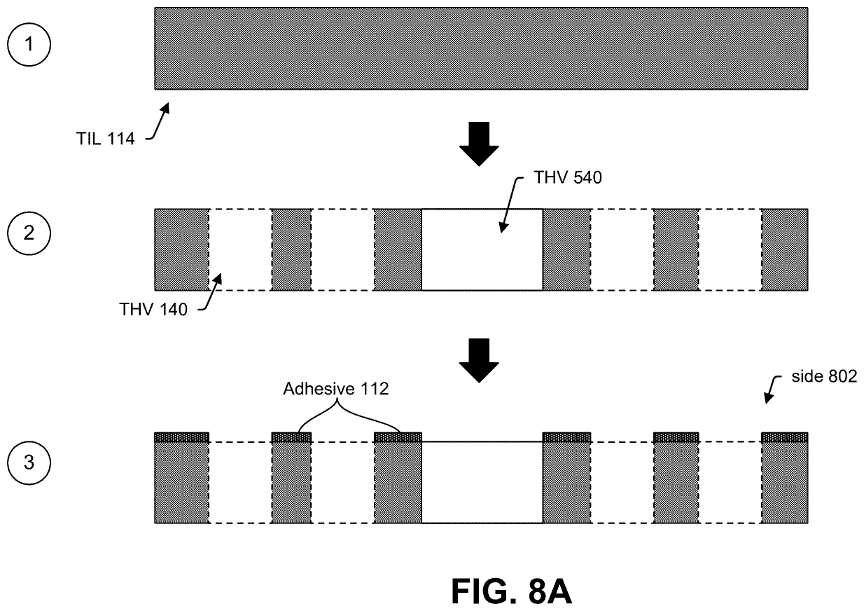

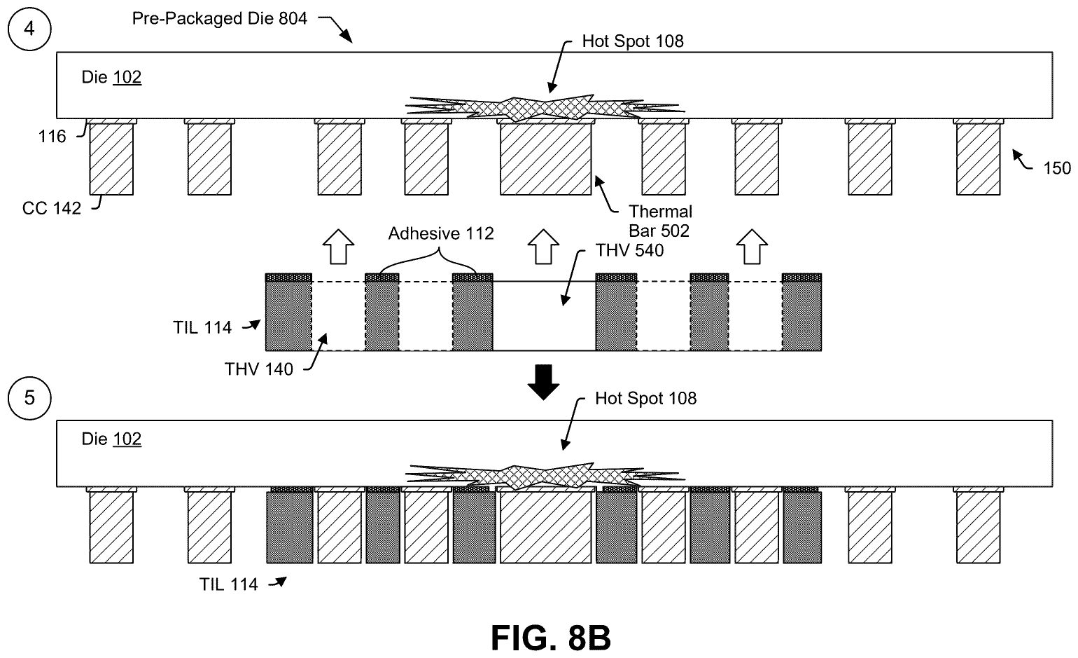

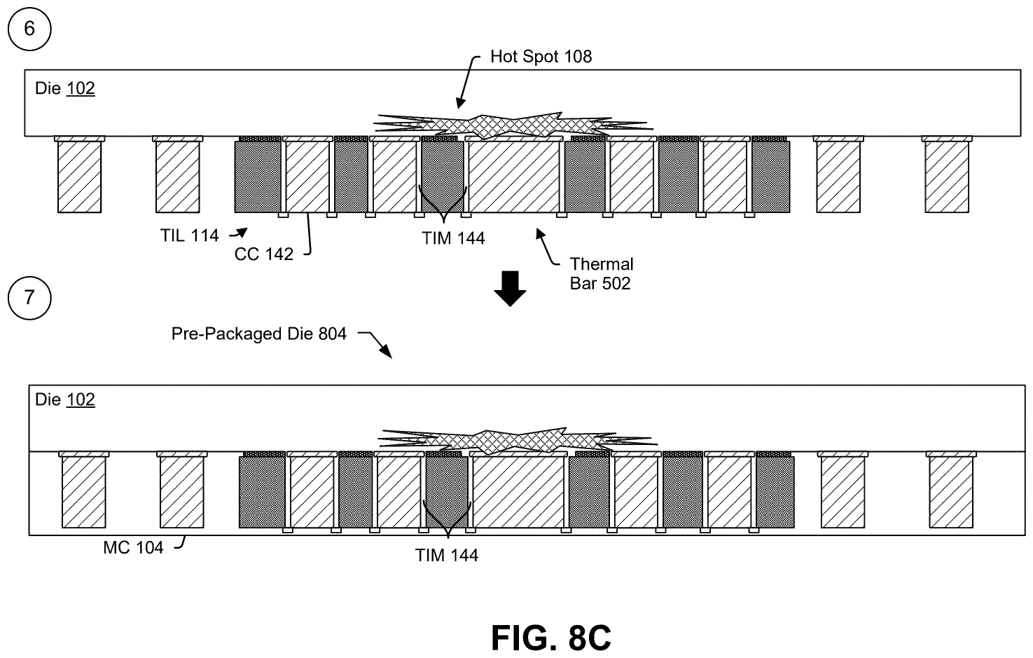

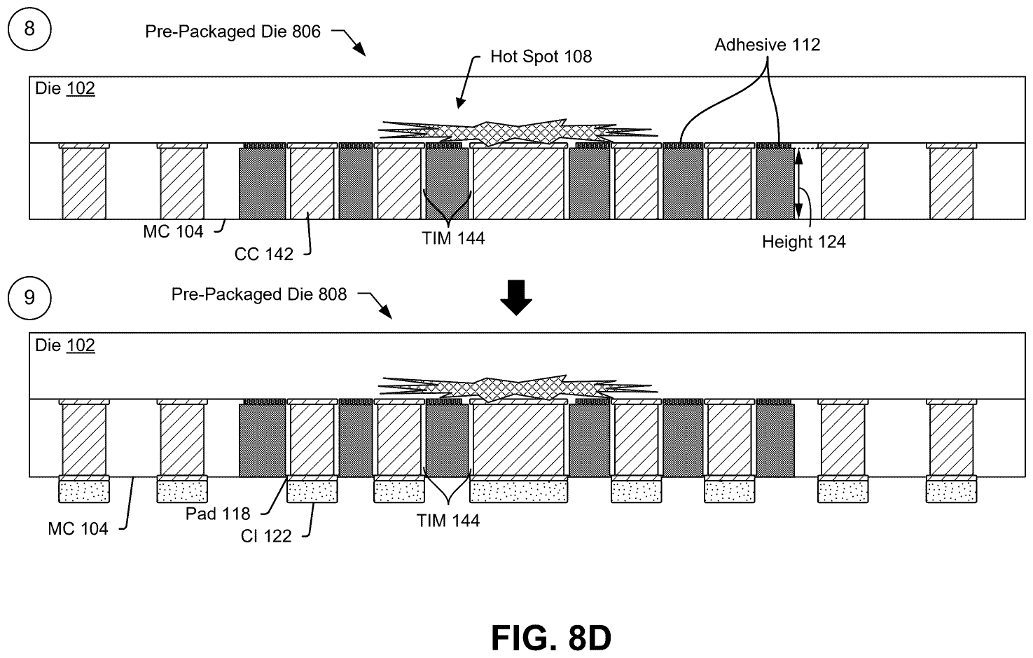

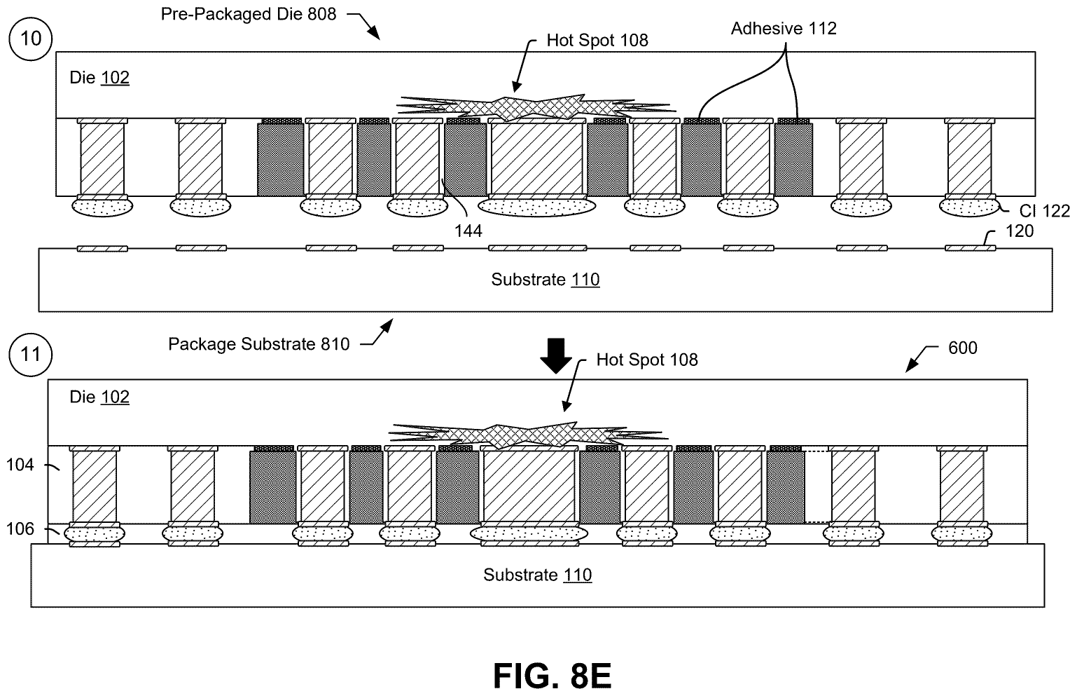

In some implementations, fabricating an IC device (e.g., any of the devices 100, 200, 300, 400, 500, 600, or 700) includes several processes. FIGS. 8A-8E illustrate Stages of an exemplary sequence for providing or fabricating an IC device including at least one TIL, as described with reference to any of FIGS. 1A-7. In some implementations, the sequence of FIGS. 8A-8E may be used to provide (e.g., during fabrication of) one or more of the devices 100, 200, 300, 400, 500, 600, or 700 of FIGS. 1A-7.

It should be noted that the sequence of FIGS. 8A-8E may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIG. 8A-8E.

Stage 1 of FIG. 8A illustrates a TIL 114. In a particular embodiment, the TIL 114 includes alumina ceramic. Stage 2 illustrates a state after THVs 140 and a THV 540 are formed in the TIL 114. For example, the THVs 140 and 540 can be formed using drilling. In a particular example, the THVs 140 and 540 are formed using laser ablation. Stage 3 illustrates a state after adhesive 112 is disposed on a side 802 of the TIL 114. In a particular example, a deposition process, a spin-on process, or a similar process can be used to apply the adhesive 112. In a particular aspect, the adhesive 112 can be photo-defined.

Stage 4 of FIG. 8B illustrates a state after a pre-packaged die 804 is aligned with the TIL 114. For example, the pre-packaged die 804 includes a die 102 with contacts 116 on a side 150 of the die 102. The contacts 116 are electrically connected to CCs 142, as described with reference to FIG. 1A. A first subset of the contacts 116 is electrically connected to first CCs 142 that are aligned with one or more TILs 114 and a second subset of the contacts 116 is electrically connected to second CCs 142 that are to extend through a MC 104 and do not have to be aligned with any TILs.

The first CCs 142 are aligned with the THVs 140 of the TIL 114. In the illustrated embodiment, the CCs 142 include the thermal bar 502 that is adjacent to a portion of the die 102 that corresponds to a hot spot 108, as described with reference to FIG. 6A. The thermal bar 502 is aligned with the THV 540. Stage 5 illustrates a state after the pre-packaged die 804 is attached to the TIL 114 using the adhesive 112.

Stage 6 of FIG. 8C illustrates a state after a TIM 144 is disposed to fill gaps between the CCs 142 and the thermally conductive material of the TIL 114. In a particular example, a deposition process, a spin-on process, or a similar process can be used to apply the TIM 144, and the TIM 144 can subsequently be cured or hardened by exposure to light, heat, and/or chemical hardening agents. In a particular aspect, the TIM 144 includes solder paste. In a particular aspect, the TIM 144 includes silver, tin, or both.

Stage 7 illustrates a state after a MC 104 is disposed on the die 102 and between the CC 142 and the TIL 114 to form a pre-packaged die 804. In a particular example, a deposition process, a spin-on process, or a similar process can be used to apply the MC 104, and the MC 104 can subsequently be cured or hardened by exposure to light, heat, and/or chemical hardening agents.

Stage 8 of FIG. 8D illustrates a state after a material removal process is applied to the pre-packaged die 804 to form a pre-packaged die 806. For example, the material removal process is performed to remove a portion of at least the MC 104, the TIM 144, the CC 142, or a combination thereof, to expose a surface of the CC 142, the thermal bar 502, the TIM 144, the TIL 114, or a combination thereof. The material removal process can include grinding operations, patterning operations, etching processes, drilling operations, laser ablation operations, other targeted material removal operations, or combinations thereof. Subsequent to performance of the material removal process, the TIL 114 has a height 124 (e.g., 40-80 micrometers).

Stage 9 illustrates a state after pads 118 and CIs 122 are formed on the pre-packaged die 806 to form a pre-packaged die 808. For example, the pads 118 and the CIs 122 can include electrical connectors (e.g., microbumps, conductive pads, or pillars) to form electrical connections via the CCs 142 to the contacts 116 of the die 102. One or more plating processes and one or more patterning processes may be used to form the pads 118 and the CIs 122. In a particular embodiment, the CIs 122 correspond to solder bumps, e.g., a grid or array of solder bumps, formed on the pads 118 that are on the CCs 142.

Stage 10 of FIG. 8E illustrates a state after aligning the pre-packaged die 808 and a package substrate 810. In an example, the package substrate 810 includes contacts 120 on a surface of a substrate 110. In a particular embodiment, the substrate 110 includes metal traces 210 electrically connected to the contact 120, as described with reference to FIG. 2A. One or more contacts 120 are aligned with respective CIs 122. In a particular embodiment, heat is applied to the CIs 122 prior or subsequent to alignment with the contacts 120.

Stage 11 illustrates a state after attachment of the pre-packaged die 808 to the package substrate 810 and deposition of a MC 106. For example, heating/reflowing can be performed on the CIs 122 to electrically connect the CIs 122 to the contacts 120. The MC 106 is disposed on the MC 104 and the TIL 114 and in between surfaces of the pads 118, the CIs 122, and the contacts 120. In a particular example, a deposition process, a spin-on process, or a similar process can be used to apply the MC 106, and the MC 106 can subsequently be cured or hardened by exposure to light, heat, and/or chemical hardening agents.

Formation of the device 600 (e.g., a packaged IC device) is complete after stage 11 of FIG. 8. However, in some implementations, one or more similar operations can be performed to form one of the devices 100, 200, 300, 400, or 500 FIGS. 1A-5B. In a particular embodiment, the CCs 142 are of the same size, exclude the thermal bar 502, or a combination thereof, as described with reference to the device 100 of FIG. 1A. In a particular embodiment, during Stage 4, the pre-packaged die 804 is aligned with multiple TILs, such as the TIL 114A and the TIL 114B, as described with reference to the device 200 of FIG. 2A. In some embodiments, the pre-packaged die 804 can include an RDL 208 between the contacts 116 and the CCs 142, as described with reference to the device 200 of FIG. 2A.

In some embodiments, a first subset of the contacts 116 is electrically connected to CCs 342 that are to extend through one or more TILs 114 and a second subset of the contacts 116 is electrically connected to CCs 142 that are to extend through the MC 104, as described with reference to the device 300 of FIG. 3A. During Stage 4, the CCs 342 are aligned with the TIL 114A and the TIL 114B, and the CCs 142 do not have to be aligned with any TILs. After Stage 5, pads 318 are formed on the CCs 342. TSVs 308 of a die 306A are electrically connected to respective pads 318 on the TIL 114A and TSVs 308 of a die 306B are electrically connected to respective pads 318 on the TIL 114B. In a particular embodiment, fabrication proceeds to Stage 9. During Stage 9, pads 118 are formed on the CCs 142 and the TSVs 308, and the CI 122 are formed on the pad 118. In a particular embodiment, after Stage 11, TIM 304 is deposited on the die 102 and a heat sink 302 is attached to the TIM 304, as described with reference to the device 300 of FIG. 3A.

In a particular embodiment, multiple pre-packaged dies are aligned with multiple TILs. For example, during Stage 4, a subset of CCs 142 electrically connected to a die 102A are aligned with THVs 140 of a TIL 114A and another subset of CCs 142 electrically connected to a die 102C are aligned with THVs 140 of a TIL 114B, as described with reference to the device 400 of FIG. 4A. In a particular embodiment, the thermal bar 502 is offset from a hot spot 108, as described with reference to the device 500 of FIG. 5A.

### Exemplary Flow Diagram of a Method for Fabricating an Integrated Device Comprising a Thermal Interposer Layer

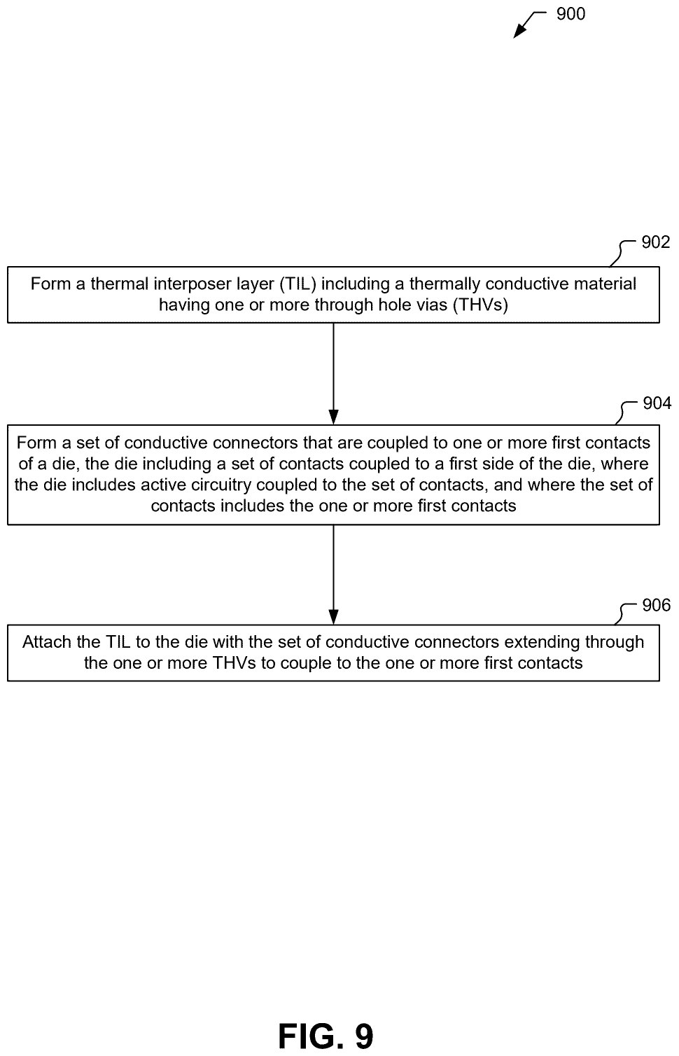

In some implementations, fabricating a IC device includes several processes. FIG. 9 illustrates an exemplary flow diagram of a method 900 for providing or fabricating an IC device including a thermal interposer layer. In some implementations, the method 900 of FIG. 9 may be used to provide or fabricate any of the devices 100, 200, 300, 400, 500, 600, or 700 of FIGS. 1A-7.

It should be noted that the method 900 of FIG. 9 may combine one or more processes in order to simplify and/or clarify the method for providing or fabricating an integrated device. In some implementations, the order of the processes may be changed or modified.

The method 900 includes, at block 902, forming a thermal interposer layer (TIL) including a thermally conductive material having one or more through hole vias (THVs). For example, Stage 2 of FIG. 8A illustrates and describes an example of forming the TIL 114 that includes a thermally conductive material having one or more THV 140, one or more THVs 540, or a combination thereof.

The method 900 includes, at block 904, forming a set of conductive connectors that are coupled to one or more first contacts of a die, the die including a set of contacts coupled to a first side of the die, where the die includes active circuitry coupled to the set of contacts, and where the set of contacts includes the one or more first contacts. For example, Stage 4 of FIG. 8B illustrates and describes an example of a pre-packaged die 804 including CCs 142 coupled to the contacts 116. The die 102 includes the contact 116 coupled to the side 150 of the die 102. The die 102 includes active circuitry coupled to the contacts 116. One or more plating processes and one or more patterning processes may be used to form the contacts 116 on the die 102, to form the CCs 142 on the contacts 116, or a combination thereof.

The method 900 includes, at block 906, attaching the TIL to the die with the set of conductive connectors extending through the one or more THVs to couple to the one or more first contacts. For example, Stage 5 of FIG. 8B illustrates and describes an example of attaching the TIL 114 to the die 102 using the adhesive 112. A first subset of the CCs 142 extend through the THVs 140 of the TIL 114 to couple to a first subset of the contacts 116.

### Exemplary Electronic Devices

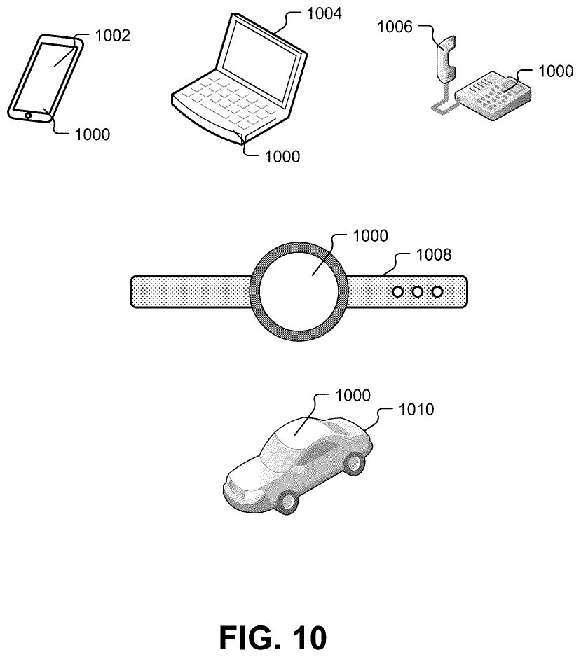

FIG. 10 illustrates various electronic devices that may include or be integrated with any of the devices 100, 200, 300, 400, 500, 600, or 700. For example, a mobile phone device 1002, a laptop computer device 1004, a fixed location terminal device 1006, a wearable device 1008, or a vehicle 1010 (e.g., an automobile or an aerial device) may include a device 1000. The device 1000 can include, for example, any of the devices 100, 200, 300, 400, 500, 600, or 700 described herein. The devices 1002, 1004, 1006 and 1008 and the vehicle 1010 illustrated in FIG. 10 are merely exemplary. Other electronic devices may also feature the device 1000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-10 may be rearranged and/or combined into a single component, process, feature or function or embodied in several components, processes, or functions. Additional elements, components, processes, and/or functions may also be added without departing from the disclosure. It should also be noted FIGS. 1-10 and its corresponding description in the present disclosure is not limited to dies and/or ICs. In some implementations, FIGS. 1-10 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a die including: a set of contacts coupled to a first side of the die; and active circuitry coupled to the set of contacts. The device also includes a thermal interposer layer (TIL) adjacent to the first side of the die, the TIL including a thermally conductive material having one or more though hole vias (THVs) aligned with one or more first contacts of the set of contacts. The device further includes a set of conductive connectors that are coupled to the one or more first contacts and that extend through the THVs.

Example 2 includes the device of Example 1 and further includes a package substrate including a second set of contacts, wherein one or more second contacts of the second set of contacts are coupled to the set of conductive connectors.

Example 3 includes the device of Example 1 or Example 2, wherein at least one THV of the one or more THVs has an oblong cross-section.

Example 4 includes the device of Example 3, wherein at least one conductive connector of the set of conductive connectors corresponds to a non-circular thermal bar that extends through the at least one THV having the oblong cross-section.

Example 5 includes the device of any of Examples 1 to 4, wherein at least one THV of the one or more THVs has a substantially circular cross-section.

Example 6 includes the device of any of Examples 1 to 5, wherein at least one of the set of conductive connectors includes copper.

Example 7 includes the device of any of Examples 1 to 6, wherein the thermally conductive material includes alumina ceramic.

Example 8 includes the device of any of Examples 1 to 7, wherein the thermally conductive material includes aluminum nitride.

Example 9 includes the device of any of Examples 1 to 8, wherein the thermally conductive material includes silicon carbide (SIC).

Example 10 includes the device of any of Examples 1 to 9, wherein the die corresponds to a chiplet that is separated from a package substrate by the TIL.

Example 11 includes the device of Example 10 and further includes a second chiplet that is separated from the package substrate by a second TIL.

Example 12 includes the device of any of Examples 1 to 11, wherein the TIL dissipates heat from the die.

Example 13 includes the device of any of Examples 1 to 12 and further includes a heat sink; and thermal interface material (TIM) adjacent to a second side of the die that is opposite the first side, wherein the TIM is between the heat sink and the die.

Example 14 includes the device of any of Examples 1 to 13 and further includes a high-bandwidth memory (HBM) module including a set of second conductive connectors that extend through the HBM module and that are aligned with the set of conductive connectors.

According to Example 15, a method of fabrication includes forming a thermal interposer layer (TIL) including a thermally conductive material having one or more through hole vias (THVs); forming a set of conductive connectors that are coupled to one or more first contacts of a die, the die including a set of contacts coupled to a first side of the die, wherein the die includes active circuitry coupled to the set of contacts, and wherein the set of contacts includes the one or more first contacts; and attaching the TIL to the die with the set of conductive connectors extending through the one or more THVs to couple to the one or more first contacts.

Example 16 includes the method of Example 15 and further includes filling gaps between the set of conductive connectors and the thermally conductive material.

Example 17 includes the method of Example 15 or Example 16, and further includes forming solder bumps on the set of conductive connectors; and electrically connecting one or more second contacts of a package substrate to the solder bumps.

Example 18 includes the method of any of Examples 15 to 17, wherein at least one THV of the one or more THVs has an oblong cross-section.

Example 19 includes the method of Example 18, wherein at least one conductive connector of the set of conductive connectors corresponds to a non-circular thermal bar that extends through the at least one THV having the oblong cross-section.

Example 20 includes the method of any of Examples 15 to 19, wherein at least one THV of the one or more THVs has a substantially circular cross-section.

Example 21 includes the method of any of Examples 15 to 20, wherein at least one of the set of conductive connectors includes copper.

Example 22 includes the method of any of Examples 15 to 21, wherein the thermally conductive material includes alumina ceramic.

Example 23 includes the method of any of Examples 15 to 22, wherein the thermally conductive material includes aluminum nitride.

Example 24 includes the method of any of Examples 15 to 23, wherein the thermally conductive material includes silicon carbide (SiC).

Example 25 includes the method of any of Examples 15 to 24, wherein the die corresponds to a chiplet that is separated from a package substrate by the TIL.

Example 26 includes the method of any of Examples 15 to 25, wherein the TIL dissipates heat from the die.

According to Example 27, a device includes a first chiplet including: a first set of contacts coupled to a first side of the first chiplet; and first active circuitry coupled to the first set of contacts. The device also includes a first thermal interposer layer (TIL) adjacent to the first side of the first chiplet, the first TIL including first thermally conductive material having one or more first though hole vias (THVs) aligned with one or more first contacts of the first set of contacts. The device further includes a first set of conductive connectors that are coupled to the one or more first contacts and that extend through the first THVs. The device also includes a package substrate including a set of substrate contacts, one or more first substrate contacts of the set of substrate contacts coupled to the first set of conductive connectors.

Example 28 includes the device of Example 27 and further includes a second chiplet including: a second set of contacts coupled to a second side of the second chiplet; and second active circuitry coupled to the second set of contacts. The device also includes a second TIL adjacent to the second side of the second chiplet, the second TIL including second thermally conductive material having one or more second THVs aligned with one or more second contacts of the second set of contacts. The device further includes a second set of conductive connectors that are coupled to the one or more second contacts and that extend through the second THVs, one or more second substrate contacts of the set of substrate contacts coupled to the second set of conductive connectors.

Example 29 includes the device of Example 27 or Example 28, wherein a first THV of the one or more first THVs has an oblong cross-section.

Example 30 includes the device of Example 29, wherein a first conductive connector of the first set of conductive connectors corresponds to a non-circular thermal bar that extends through the first THV.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a die including:
a set of contacts coupled to a first side of the die; and
active circuitry coupled to the set of contacts;
a thermal interposer layer (TIL) adjacent to the first side of the die, the TIL including a thermally conductive material having one or more though hole vias (THVs) aligned with one or more first contacts of the set of contacts; and
a set of conductive connectors that are coupled to the one or more first contacts and that extend through the THVs.

2. The device of claim 1, further comprising a package substrate including a second set of contacts, wherein one or more second contacts of the second set of contacts are coupled to the set of conductive connectors.

3. The device of claim 1, wherein at least one THV of the one or more THVs has an oblong cross-section.

4. The device of claim 3, wherein at least one conductive connector of the set of conductive connectors corresponds to a non-circular thermal bar that extends through the at least one THV having the oblong cross-section.

5. The device of claim 1, wherein at least one THV of the one or more THVs has a substantially circular cross-section.

6. The device of claim 1, wherein at least one of the set of conductive connectors includes copper.

7. The device of claim 1, wherein the thermally conductive material includes alumina ceramic.

8. The device of claim 1, wherein the thermally conductive material includes aluminum nitride.

9. The device of claim 1, wherein the thermally conductive material includes silicon carbide (SIC).

10. The device of claim 1, wherein the die corresponds to a chiplet that is separated from a package substrate by the TIL.

11. The device of claim 10, further comprising a second chiplet that is separated from the package substrate by a second TIL.

12. The device of claim 1, wherein the TIL dissipates heat from the die.

13. The device of claim 1, further comprising:
a heat sink; and
thermal interface material (TIM) adjacent to a second side of the die that is opposite the first side, wherein the TIM is between the heat sink and the die.

14. The device of claim 1, further comprising a high-bandwidth memory (HBM) module including a set of second conductive connectors that extend through the HBM module and that are aligned with the set of conductive connectors.

15. A method of fabrication comprising:
forming a thermal interposer layer (TIL) including a thermally conductive material having one or more through hole vias (THVs);
forming a set of conductive connectors that are coupled to one or more first contacts of a die, the die including a set of contacts coupled to a first side of the die, wherein the die includes active circuitry coupled to the set of contacts, and wherein the set of contacts includes the one or more first contacts; and
attaching the TIL to the die with the set of conductive connectors extending through the one or more THVs to couple to the one or more first contacts.

16. The method of claim 15, further comprising filling gaps between the set of conductive connectors and the thermally conductive material.

17. The method of claim 15, further comprising:
forming solder bumps on the set of conductive connectors; and
electrically connecting one or more second contacts of a package substrate to the solder bumps.

18. The method of claim 15, wherein at least one THV of the one or more THVs has an oblong cross-section.

19. The method of claim 18, wherein at least one conductive connector of the set of conductive connectors corresponds to a non-circular thermal bar that extends through the at least one THV having the oblong cross-section.

20. The method of claim 15, wherein at least one THV of the one or more THVs has a substantially circular cross-section.

21. The method of claim 15, wherein at least one of the set of conductive connectors includes copper.

22. The method of claim 15, wherein the thermally conductive material includes alumina ceramic.

23. The method of claim 15, wherein the thermally conductive material includes aluminum nitride.

24. The method of claim 15, wherein the thermally conductive material includes silicon carbide (SIC).

25. The method of claim 15, wherein the die corresponds to a chiplet that is separated from a package substrate by the TIL.

26. The method of claim 15, wherein the TIL dissipates heat from the die.

27. A device comprising:
a first chiplet including:
a first set of contacts coupled to a first side of the first chiplet; and
first active circuitry coupled to the first set of contacts;
a first thermal interposer layer (TIL) adjacent to the first side of the first chiplet, the first TIL including first thermally conductive material having one or more first though hole vias (THVs) aligned with one or more first contacts of the first set of contacts;
a first set of conductive connectors that are coupled to the one or more first contacts and that extend through the first THVs; and
a package substrate including a set of substrate contacts, one or more first substrate contacts of the set of substrate contacts coupled to the first set of conductive connectors.

28. The device of claim 27, further comprising:
a second chiplet including:
a second set of contacts coupled to a second side of the second chiplet; and
second active circuitry coupled to the second set of contacts;
a second TIL adjacent to the second side of the second chiplet, the second TIL including second thermally conductive material having one or more second THVs aligned with one or more second contacts of the second set of contacts; and
a second set of conductive connectors that are coupled to the one or more second contacts and that extend through the second THVs, one or more second substrate contacts of the set of substrate contacts coupled to the second set of conductive connectors.

29. The device of claim 27, wherein a first THV of the one or more first THVs has an oblong cross-section.

30. The device of claim 29, wherein a first conductive connector of the first set of conductive connectors corresponds to a non-circular thermal bar that extends through the first THV.
